(19) United States
(12) Patent Application Publication
(10) Pub. No.: US 2013/0087371 A1
(43) Pub. Date: Apr. 11, 2013

(54) ELECTRONIC PACKAGING CONNECTOR AND METHODS FOR ITS PRODUCTION

(71) Applicant: Georg Meyer-Berg, Muenchen (DE)

(72) Inventor: Georg Meyer-Berg, Muenchen (DE)

(73) Assignee: INFINEON TECHNOLOGIES AG, Neubiberg (DE)

(21) Appl. No.: 13/270,268

(22) Filed: Oct. 11, 2011

(51) Int. Cl. H05K 1/09; H01R 9/00; H05K 1/11

(52) U.S. Cl. 174/257; 174/261; 29/842

(57) ABSTRACT

A surface mount packaging connector includes an elastic conductor, an interconnect pad, and a conductive layer. The elastic conductor has a top surface. The interconnect pad is electrically coupled to the elastic conductor. The top surface of the elastic conductor is arranged away from the interconnect pad. The conductive layer is on the top surface of the elastic conductor. The conductive layer provides an increased electrically conductive surface area and may also be a solderable surface.

### FIELD OF THE DISCLOSURE

This disclosure relates to apparatus and methods for electronic packaging for integrated circuits (IC) and, more particularly, to apparatus and methods for surface-mount packaging connectors.

### BACKGROUND

ICs play an increasingly important role in modern life. Products which include ICs can be found in many modern products, and as such there is a continuing need to provide more capable products at decreased costs. The famous so called “Moore's law”, for instance, has predicted a trend for the last half a century, namely that the number of transistors placed in an IC doubles approximately every two years.

In conjunction with developments in IC technology, IC packaging design has trended towards smaller, thinner, lighter, and more robust packaging. A critical part of IC packaging is the package connectors to connect the IC package with external circuitry such as, for example, a printed circuit board (PCB). Given the trend of smaller, thinner, lighter IC packaging, reliable package connectors are difficult to develop and have thus lead to intensive research and development.

FIG. 1 illustrates a cross-sectional view of a surface mount packaging connector with an electrically conductive contact ball. In particular, surface mount packaging connector 10 includes an electrically conductive contact ball 12, an interconnect pad 14, and an electronic package 16. Interconnect pad 14 is usually embedded into electronic package 16 during its fabrication, whereas electrically conductive contact ball 12 is usually soldered onto interconnect pad 14 in a later manufacturing process. The solder serves to both physically and electrically couple electrically conductive contact ball 12 to interconnect pad 14.

Electronic package 16 may include several layers as depicted. One of the layers of electronic package 16 is an outer layer, and in particular comes in contact with electrically conductive contact ball 12 at stress points 18. Electrically conductive contact ball 12 is constructed of a chosen material that may have a coefficient of thermal expansion (CTE) that is different than the material and CTE of the outer layer of electronic package 16 at stress points 18. As a result of the CTE mismatch between the two materials, thermal cycling of surface mount packaging connector 10 results in permanent ongoing stress of the solder at stress points 18. That is, because of asymmetrical thermal expansion of electronic package 16 and further external electronic assemblies, such as a connectable PCB board, the solder may start to crack and may eventually break the electrical connection between electrically conductive contact ball 12 and interconnect pad 14. After board level assembly, such a break in the electrical connection between electrically conductive contact ball 12 and interconnect pad 14 may render the product inoperable since surface mount packaging connector 10 serves to electrically connect electronic package 16 with further external electronic assemblies.

Other external stresses, such as mechanical vibrations or shocks, may add additional or separate stresses to surface mount packaging connector 10. Such external stresses are not uncommon in assemblies which include IC packages. For example, an automobile may include an embedded computer system which employs IC packaging including surface mount packaging connector 10. In addition to internally generated heat, the embedded computer system in the automobile may likely experience external heat sources, climate variation, and mechanical shocks such as vibrations. Owing to these effects, surface mount packaging connector 10 as used in such an automotive embedded computer system may experience solder cracking and eventual product failure. Trends towards smaller, thinner, and lighter packaging add further complexity in producing a robust surface mount packaging connector that can reliably withstand these stresses.

### SUMMARY

In a first implementation a surface mount packaging connector includes an elastic conductor, an interconnect pad, and a conductive layer. The elastic conductor has a top surface. The interconnect pad is electrically coupled to the elastic conductor. The top surface of the elastic conductor is arranged away from the interconnect pad. The conductive layer is on the top surface of the elastic conductor. The conductive layer provides an increased electrically conductive surface area.

One or more of the following features may be included. The surface mount packaging connector may be employed in a land grid array (LGA). The conductive layer may be a metal dust. The conductive layer may be applied as dirty plasma. The conductive layer may have electrical conductivity within at least 10% of copper electrical conductivity. The conductive layer may be composed of a metal such as copper, copper-alloys, gold, gold-alloys, silver, silver-alloys, nickel, and nickel-alloys. The elastic conductor may have thermal conductivity between 2 and 15 watts per meter Kelvin and volume resistivity between 40 and 120 micro-ohms per centimeter. The surface mount packaging connector may be employed on a surface for package assembly. The surface for package assembly may be a PCB. The elastic conductor may be a glue that has been cured and the conductive layer may be formed integrally during the curing of the glue. The elastic conductor may be composed such that the elastic conductor can elongate relative to the interconnect pad by at least 10% while remaining in electrical contact therewith.

In another implementation a surface mount packaging connector includes an electrically conductive contact ball, an elastic conductor, and an interconnect pad. The electrically conductive contact ball has a surface, and the elastic conductor is affixed and electrically coupled to the surface of the conductive contact ball. The interconnect pad is electrically coupled to the elastic conductor. The electrically conductive contact ball is elastically movable relative to the interconnect pad while remaining in electrical contact with the interconnect pad.

One or more of the following features may be included. The surface mount packaging connector may be employed in a ball grid array (BGA) or an embedded wafer level ball grid array (eWLB). The surface mount packaging connector may also include a solderable layer on the elastic conductor at the affixing point between the electrically conductive contact ball and the elastic conductor. The electrically conductive contact ball may be a solder ball and may thereby be affixed through solder processing onto the solderable layer. The conductive layer may be a metal dust. The conductive layer may be applied as dirty plasma. The solderable layer may have an electrical conductivity within at least 10% of copper electrical conductivity. The conductive layer may be composed of a metal such as copper, copper-alloys, gold, gold-alloys, silver, silver-alloys, nickel, and nickel-alloys. The elastic conductor may be a glue that has been cured and the solderable layer may be formed integrally during the curing of the glue. The electrically conductive contact ball may have an electrical conductivity within at least 10% of copper electrical conductivity. The electrically conductive contact ball may be composed of a metal such as copper, copper-alloys, gold, gold-alloys, silver, silver-alloys, nickel, nickel-alloys, tin, and tin-alloys. The electrically conductive contact ball may have an organic surface protection (OSP) layer affixed to another part of the surface of the electrically conductive contact ball. The electrically conductive contact ball may have a protective metal layer affixed to a second portion of the surface of the electrically conductive contact ball, the protective metal layer capable of preventing oxidation of the electrically conductive contact ball. The elastic conductor may have thermal conductivity of between 2 and 15 watts per meter Kelvin and volume resistivity between 40 and 120 micro-ohms per centimeter. The surface mount packaging connector may be employed on the base of a PCB. The elastic conductor may be composed such that movement of the electrically conductive contact ball relative to the interconnect pad can elongate the elastic conductor by at least 10% while remaining in electrical contact with the interconnect pad.

In a further implementation a method for producing a surface mount packaging connector includes providing an interconnect pad, applying an elastic conductor to the interconnect pad such that the interconnect pad is electrically coupled to the elastic conductor, the elastic conductor having a top surface arranged away from the interconnect pad, and affixing a electrically conductive contact ball to the top surface of the elastic conductor. The electrically conductive contact ball is elastically movable relative to the interconnect pad while remaining in electrical contact therewith.

One or more of the following features may be included. The elastic conductor may be composed such that movement of the electrically conductive contact ball relative to the interconnect pad can elongate the elastic conductor by at least 10% while remaining in electrical contact therewith. The electrically conductive contact ball may have an electrical conductivity within at least 10% of copper electrical conductivity. The elastic conductor may have thermal conductivity between 2 and 15 watts per meter Kelvin and volume resistivity between 40 and 120 micro-ohms per centimeter. The electrically conductive contact ball may be composed of a metal such as copper, copper-alloys, gold, gold-alloys, silver, silver-alloys, nickel, nickel-alloys, tin, and tin-alloys. The electrically conductive contact ball may have an OSP layer affixed to another part of the surface of the electrically conductive contact ball. The electrically conductive contact ball may have a protective metal layer affixed to a second portion of the surface of the electrically conductive contact ball, the protective metal layer capable of preventing oxidation of the electrically conductive contact ball.

In yet a further implementation a method for producing a surface mount packaging connector includes providing an interconnect pad, applying an elastic conductor to the interconnect pad such that the interconnect pad is electrically coupled to the elastic conductor, the elastic conductor having a top surface arranged away from the interconnect pad, and applying a conductive layer on the top surface of the elastic conductor.

One or more of the following features may be included. The elastic conductor may be a glue that has been cured. The surface mount packaging connector may also include a solder ball affixed to the conductive layer, such that the conductive layer is a solderable layer, and the solder ball is thereby affixed through solder processing onto the solderable layer. The elastic conductor may be composed such that movement of the solder ball relative to the interconnect pad can elongate the elastic conductor by at least 10% while remaining in electrical contact therewith. The conductive layer may provide an increased electrically conductive surface with electrical conductivity within at least 10% of copper electrical conductivity. The elastic conductor may have thermal conductivity between 2 and 15 watts per meter Kelvin and volume resistivity between 40 and 120 micro-ohms per centimeter. The conductive layer may be composed of a metal such as copper, copper-alloys, gold, gold-alloys, silver, silver-alloys, nickel, and nickel-alloys.

### BRIEF DESCRIPTION OF THE DRAWINGS

To further clarify the above and other advantages and features of the present invention, a more particular description of the invention will be rendered by reference to specific embodiments thereof that are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates a cross-sectional view of a surface mount packaging connector with an electrically conductive contact ball;

FIG. 2 illustrates a cross-sectional view of an exemplary surface mount packaging connector with an elastic conductor;

FIG. 3 illustrates a cross-sectional view of an exemplary surface mount packaging connector with a conductive layer on an elastic conductor;

FIG. 4 illustrates a cross-sectional view of an exemplary surface mount packaging connector with a conductive layer on an elastic conductor and an electrically conductive contact ball;

FIG. 5 illustrates a cross-sectional view of an exemplary surface mount packaging connector with a conductive layer on an elastic conductor, as shown in FIG. 3, connected to a PCB;

FIG. 6 illustrates a cross-sectional view of an exemplary surface mount packaging connector with an elastic conductor and an electrically conductive contact ball;

FIG. 7 illustrates a cross-sectional view of an exemplary surface mount packaging connector with an elastic conductor and an electrically conductive contact ball with OSP; and

FIG. 8 illustrates a cross-sectional view of an exemplary surface mount packaging connector with an elastic conductor and an electrically conductive contact ball, as shown in FIG. 6, connected to a PCB.

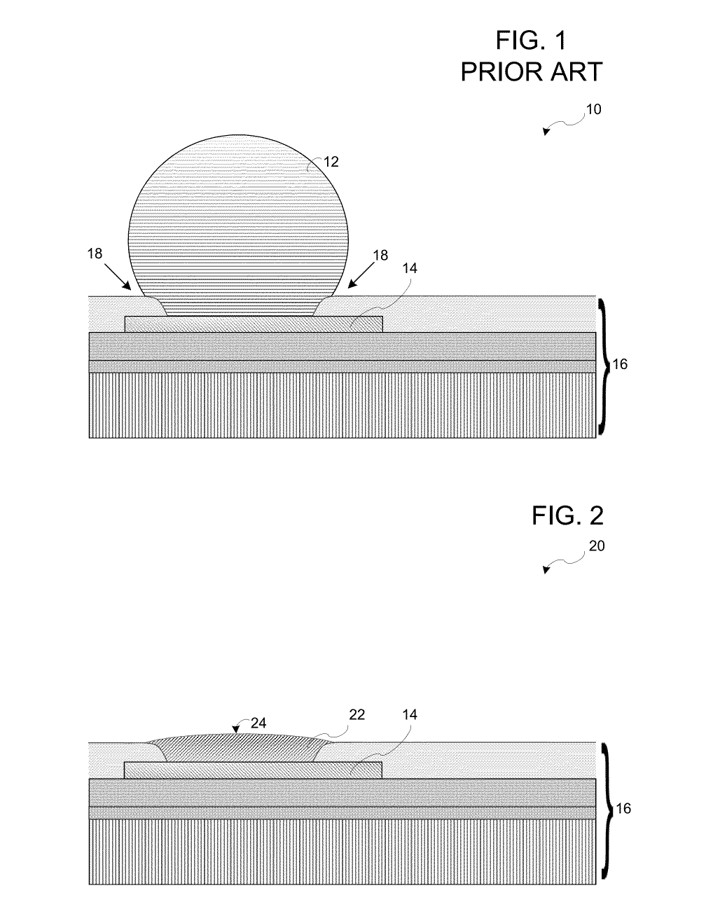

### DETAILED DESCRIPTION

Reference will now be made to figures wherein like structures will be provided with like reference designations. It is understood that the drawings are diagrammatic and schematic representations of exemplary embodiments of the invention, and are not limiting of the present invention nor are they necessarily drawn to scale.

FIG. 2 illustrates a cross-sectional view of an exemplary surface mount packaging connector with an elastic conductor. Surface mount packaging connector 20 includes elastic conductor 22 electrically coupled to interconnect pad 14. Elastic conductor 22 has top surface 24 arranged away from interconnect pad 14 which may be used to electrically connect electronic package 16 with further external electronic assemblies. Elastic conductor 22, as is implied, is both electrically conductive and elastic in nature, and surface mount packaging connector 20 may, for example, be used as a packaging connector in LGA packages.

Several glues are both electrically conductive and elastic, and retain such properties even after curing. Such glues can therefore be used as elastic conductor 22, or in other words, elastic conductor 22 may be a glue that, for example, has been cured. Such glues include, for example, MT815 or DA-6534, made respectively by the Lord Corporation and the Dow Corning Corporation. The Tanaka Kikinzoku International company manufactures TS-333 or TS-368 that can also be used as elastic conductor 22.

More generally the electrical properties of elastic conductor 22 should preferably have thermal conductivity between 2 and 15 watts per meter Kelvin (W/(m·K)) and electrical resistivity between 40 and 120 micro-ohms per centimeter (μΩ/cm). More particularly, while the preference of between 2 and 15 W/(m·K) describes thermal conductivity, it more generally is used to describe the likely electrical conductivity of elastic conductor 22. That is, low thermal conductivity generally directly relates to poor electrical conductivity.

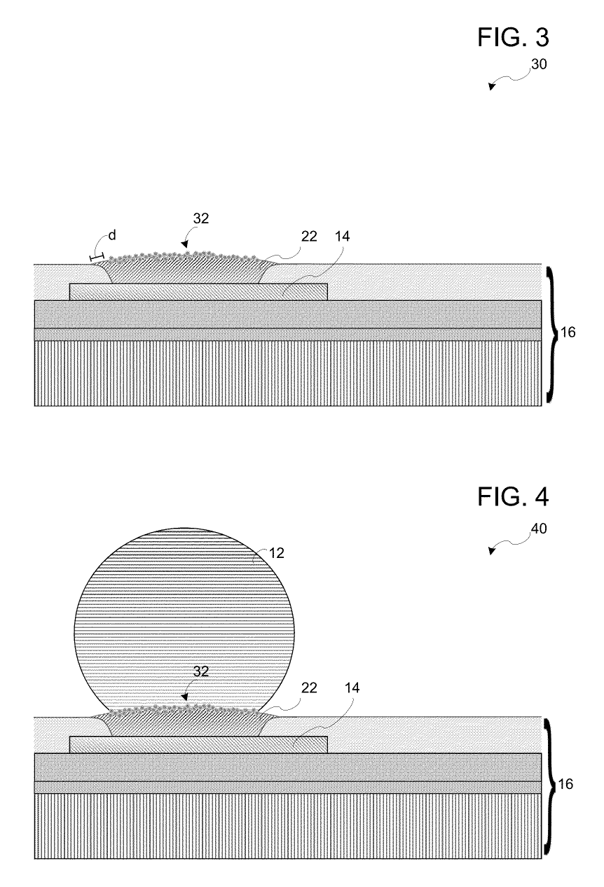

FIG. 3 illustrates a cross-sectional view of an exemplary surface mount packaging connector with a conductive layer on an elastic conductor. Similar to surface mount packaging connector 20, surface mount packaging connector 30 includes elastic conductor 22 electrically coupled to interconnect pad 14. While elastic conductor 22 has a top surface arranged away from interconnect pad 14, conductive layer 32 covers the top surface of elastic conductor 22. Preferably, the outermost rim or edge of the top surface of elastic conductor 22 (e.g. the perimeter of the top surface of elastic conductor 22 defined by distance d at the interface of the top layer of electronic package 16 and the top surface of elastic conductor 22), however, is not covered by conductive layer 32. Conductive layer 32 may be a metal dust and may be applied as dirty plasma. Alternatively, conductive layer 32 may be formed of constituents of the glue, such as during the curing thereof The curing process would then integrally form elastic conductor 22 and a conductive layer 32, such as by migration of constituents of the glue to the surface during curing.

Conductive layer 32 may be a solderable layer. A solderable layer is capable of being soldered to with a solder, while also not allowing the solder to penetrate through the solderable layer during soldering. Thus after the glue is cured conductive layer 32 may be such that solderable particles are firmly but elastically connected to elastic conductor 22. If conductive layer 32 is generated by curing the glue, conductive layer 32 is preferably solderable such that conductive layer 32 does not completely dissolve with solder processing. Moreover, to the extent that conductive layer 32 is soldered to directly, the conductive layer must remain sufficiently distinct to retain its conductive properties after soldering. Likewise, it must not diffuse into or react with elastic conductor 22, such that elastic conductor 22 becomes inelastic due to the soldering process.

Conductive layer 32 may be composed of highly conductive metal such as, for example, copper, copper-alloys, gold, gold-alloys, silver, silver-alloys, nickel, and nickel-alloys or a mixture thereof. For example, conductive layer 32 may have an electrical conductivity within at least 10% of copper electrical conductivity. Conductive layer 32 may provide a solderable surface. Conductive layer 32 may alternatively or additionally provide an increased electrically conductive surface area as a terminus for connection to elastic conductor 22, which may be used to electrically connect electronic package 16 with further external electronic assemblies such as a PCB. When surface mount packaging connector 30 is employed, for example, in a packaging connector for LGA packages, a larger interconnect pad is usually provided, as compared to interconnect pads on BGAs or eWLBs. For example, conductive layer 32 may be on the order of a 3×5 or a 10×8 square millimeter area as employed in LGA packages. As employed in BGA packages, conductive layer 32 may be on the order of a 0.25 to 1.5 millimeter diameter, for example.

Optimal thickness of elastic conductor 22 is based on the CTE mismatch and distance to neutral point (DNP) between interconnect pad 14, conductive layer 32, and further external electronic assemblies, such as a connectable PCB board. More particularly, the thickness of elastic conductor 22 should be chosen such that excessive elongation of the elastic conductor does not occur. While a thick application of elastic conductor 22 may increase its durability, the durability gained by increased thickness should be balanced with other requirements that push towards a thinner application of elastic conductor 22. Cooling of electronic package 16 may be hampered, for example, as a result of a thick application of elastic conductor 22. Overall package weight, size, thickness and cost may also, for example, be negatively affected by a thick application of elastic conductor 22. Generally when elastic conductor 22 is applied to a larger surface area the thickness of elastic conductor 22 may be reduced. Elongation to break should, preferably, be at least 10%. Given a set of product dimensions, calculation can be made of the likely elongation distances that elastic conductor 22 may experience during the life of electronic package 16 as an absolute dimension or as a percentage of another dimension, such as that of the elastic conductor. Elastic conductor 22 may be correspondingly applied such that the likely elongation of elastic conductor 22 is below 10% while still meeting the absolute dimension of expected movement between the attached devices. As an example, a given likely elongation distance may be 20 micro-meters. Thus a given material to form an elastic conductor may be applied in such a manner that elastic conductor 22 can reliably withstand displacement of about 20 micro-meters. It is foreseeable that some applications may necessitate elongation to break beyond 10%. In other applications, it may be desirable to accommodate greater displacement, or a smaller percentage of elongation through thicker application of elastic conductor 22, keeping in mind the tradeoff between elasticity and thickness described above.

Surface mount packaging connector 30 may also be employed on the base of a PCB. That is, surface mount packaging connector 30 is not limited to surface mount packages, but also to other surfaces needing such an electrical connector, for example for connection to surface mount devices.

FIG. 4 illustrates a cross-sectional view of an exemplary surface mount packaging connector with a conductive layer on an elastic conductor and an electrically conductive contact ball. Surface mount packaging connector 40 includes an electrically conductive contact ball 12, an elastic conductor 22, and an interconnect pad 14. Elastic conductor 22 is affixed and electrically coupled to a portion of the surface of electrically conductive contact ball 12. Electrically conductive contact ball 12 is thus elastically movable relative to interconnect pad 14 while remaining in electrical contact therewith. While a thick application of elastic conductor 22 may increase its durability, the durability gained by increased thickness should be balanced with other considerations based on the expected operating conditions the product may encounter. Preferably the application of elastic conductor 22 allows movement of electrically conductive contact ball 12 relative to interconnect pad 14 by at least 10% without interrupting the electrical contact between interconnect pad 14 and electrically conductive contact ball 12.

Conductive layer 32, which may be applied as disclosed in FIG. 3, is located at the affixing point between electrically conductive contact ball 12 and elastic conductor 22 and may be a solderable layer. Conductive layer 32 may thereby provide a solderable surface and/or an increased conductive surface area relative to application of contact ball 12, for example, directly to elastic conductor 22. Electrically conductive contact ball 12 may be a solder ball such that it solders to conductive layer 32 and thereby affixes and electrically couples electrically conductive contact ball 12 to elastic conductor 22. A solder ball is a relatively spherical ball that is usually composed of a low-melting metal alloy. Conductive layer 32 may itself be capable of solder processing, thereby being capable of being attached with solder means to conductive layer 32. Thus, electrically conductive contact ball 12 is 3-dimensionally flexibly attached to electronic package 16 by way of interconnect pad 14, elastic conductor 22, and conductive layer 32. Further, a CTE mismatch between electronic package 16, electrically conductive contact ball 12, and further external electronic assemblies, such as a connectable PCB board is less likely to cause stress to the solder. As a result, the solder is less likely to crack and break the electrical connection between electrically conductive contact ball 12 and interconnect pad 14, and the product is more likely to continue proper operation despite thermal cycling and mechanical stresses. These advantages are useful, for example, in BGA or eWLB configurations. Thus surface mount packaging connector 40 may be employed in a BGA or an eWLB to take advantage of the increased reliability of surface mount packaging connector 40.

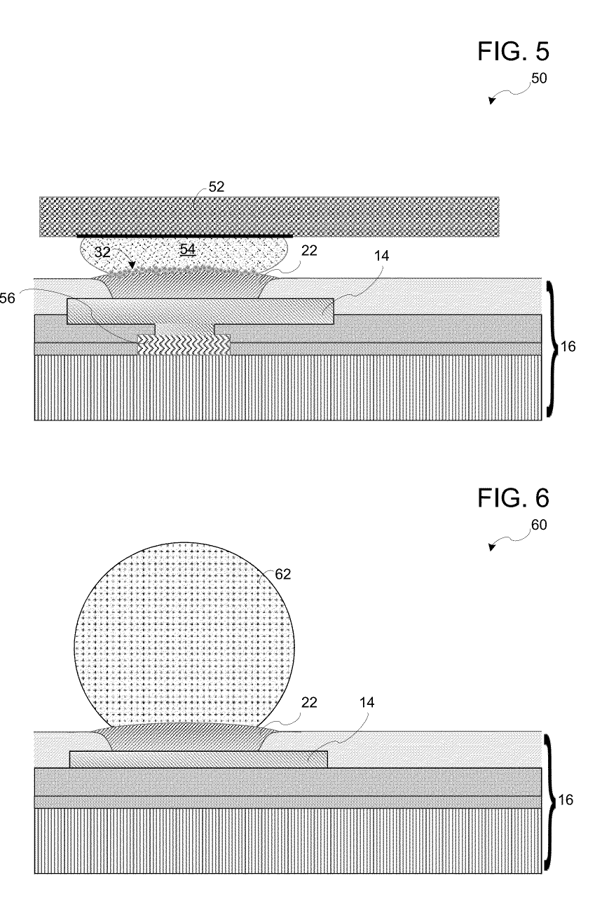

FIG. 5 illustrates a cross-sectional view of an exemplary surface mount packaging connector with a conductive layer on an elastic conductor, as shown in FIG. 3, connected to a PCB. In particular, surface mount packaging connector 50 is shown as operationally connected. PCB 52 has PCB contact 54 attached to it. Electronic package 16 is thereby electrically connected to PCB 52 though interconnect pad 14, elastic conductor 22, and conductive layer 32. Thus electronic package 16 is capable of being electrically connected with PCB 52, or more generally with other electronic components connected to PCB 52. Via 56 is also illustrated, and in some applications may be used to allow electrically conductive through-chip connections between distinct layers of electronic package 16. As depicted in the drawing, surface mount packaging connector 50 may serve, for example, as a flexible LGA contact. Conductive layer 32 may be on the order of, for example, a 3×5 or a 10×8 square millimeter area as employed in LGA packages. Preferably surface mount packaging connector 50 is cleaned and/or OSP processed prior to usage as a flexible LGA contact. Likewise, the described technique may be used in creating surface mount receiving contacts on a PCB for connecting packages to the PCB.

FIG. 6 illustrates a cross-sectional view of an exemplary surface mount packaging connector with an elastic conductor and an electrically conductive contact ball. Elastic conductor 22 is applied to interconnect pad 14 such that interconnect pad 14 is electrically coupled to elastic conductor 22. Elastic conductor 22 has a top surface arranged away from the interconnect pad to which electrically conductive contact ball 62 is attached.

Electrically conductive contact ball 62 may be added during the production of surface mount packaging connector 60 before elastic conductor 22 is cured. Thus electrically conductive contact ball 62 is affixed to elastic conductor 22 as elastic conductor 22 is cured. In this manner, a bond between electrically conductive contact ball 62 and elastic conductor 22 can be accomplished without the use of an intermediate conductive layer 32 shown in previous figures.

Electrically conductive contact ball 62 is thus 3-dimensionally flexibly attached to electronic package 16 by way of interconnect pad 14, and elastic conductor 22. A CTE mismatch between electronic package 16, electrically conductive contact ball 62, and further external electronic assemblies, such as a connectable PCB board is therefore less likely to break the electrical connection between electrically conductive contact ball 62 and interconnect pad 14 during thermal cycling, and the product is more likely to continue proper operation despite thermal cycling and mechanical stresses.

Electrically conductive contact ball 62 may be constructed from a material that has high electrical conductivity, for example metals such as copper, copper-alloys, gold, gold-alloys, silver, silver-alloys, nickel, and nickel-alloys or a mixture thereof. A relatively high electrical conductivity may compensate for some of the end-to-end conductivity previously provided in part by conductive layer 32 in previous figures. A Copper-iron alloy, for example copper-iron alloy number 194, may have sufficiently good conductivity in comparison to pure copper when used for electrically conductive contact ball 62. Likewise, a copper-tin alloy, as another example, may also function well, and may be less sensitive to oxidation. Since electrically conductive contact ball 62 is not attached by solder means, electrically conductive contact ball 62 may be constructed from materials that do not melt during soldering such as, for example, copper-based metals. Thus after the curing process electrically conductive contact ball 62 may be firm, but elastically affixed to electronic package 16 by means of elastic conductor 22. In general, electrically conductive contact ball 62 should preferably be compatible with solder processing, and have electrical conductivity that is at least within about 10% of the conductivity of copper.

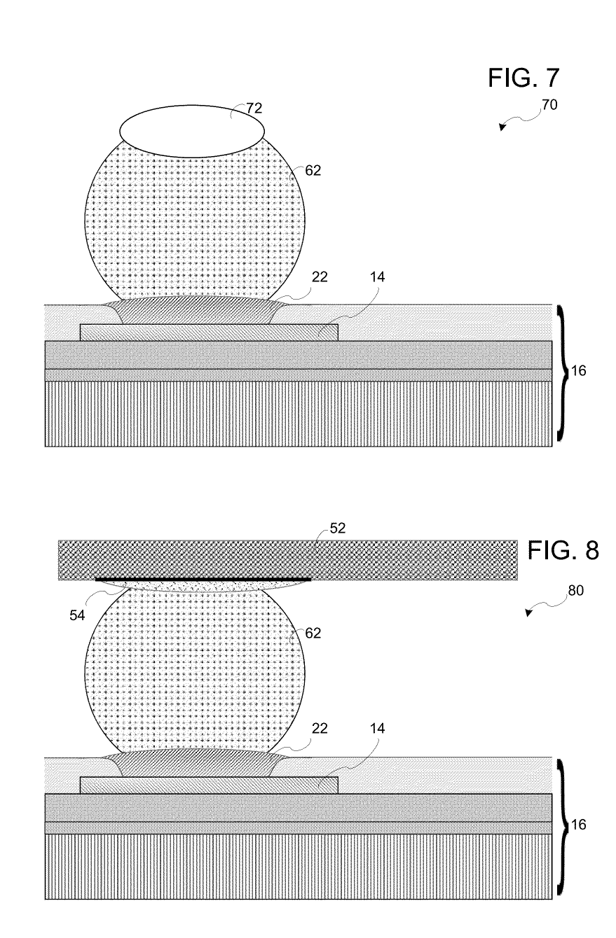

FIG. 7 illustrates a cross-sectional view of an exemplary surface mount packaging connector with an elastic conductor and an electrically conductive contact ball with OSP. Surface mount packaging connector 70 has OSP 72 applied on a portion of electrically conductive contact ball 62. OSP 72 is a water-based organic compound that selectively bonds to copper and provides an organometallic layer that protects electrically conductive contact ball 62. OSP 72, may for example, provide better storage time for electrically conductive contact ball 62 by providing thermal protection during soldering and preventing oxidation. OSP 72 is optional depending on, for example, the material used to construct electrically conductive contact ball 62. For example, electrically conductive contact ball 62 may be composed of copper, copper-alloys, gold, gold-alloys, silver, silver-alloys, nickel, and nickel-alloys. Electrically conductive contact ball 62 may also be protected with a metal layer capable of preventing oxidation of electrically conductive contact ball 62.

FIG. 8 illustrates a cross-sectional view of an exemplary surface mount packaging connector with an elastic conductor and an electrically conductive contact ball, as shown in FIG. 3, connected to a PCB. In particular, surface mount packaging connector 80 is shown as operationally connected. PCB 52 has PCB contact 54 attached to it. Electronic package 16 is thereby electrically connected to PCB 52 though interconnect pad 14, elastic conductor 22, and electrically conductive contact ball 62. Thus electrical contact between electronic package 16 and PCB 52, or more generally between electronic package 16 and other electronic components connected to PCB 52 can be reliably provided. Surface mount packaging connector 50 may serve, for example, in modern package connectors such as a flexible BGA or eWLB contact. That is, as used in modern package connectors such a BGA or eWLB contact, the electrically conductive contact balls may flexibly move relative to their respective interconnect pads while remaining in electrical contact therewith. Likewise, the described technique may be used in creating surface mount receiving contacts on a PCB for connecting packages to the PCB.

A person skilled in the art will recognize that combinations of the above exemplary embodiments may be formed. For example, electrically conductive contact ball 62 may be used in combination with conductive layer 32. OSP 72 may be used in combination with conductive layer 32. OSP 72 may be used in combination with electrically conductive contact ball 12. Electrically conductive contact ball 12 may be a solder ball and may be directly affixed to elastic conductor 22 without solder or a conductive layer. Electronic package 16 may be, for example, any type of IC package including, for instance, wafer level packages.

The present invention may be embodied in other specific forms without departing from its spirit or essential characteristics. The described embodiments are to be considered in all respects only as illustrative, not restrictive. The scope of the invention is, therefore, indicated by the appended claims rather than by the foregoing description. All changes that come within the meaning and range of equivalency of the claims are to be embraced within their scope.

What is claimed is:

1. A surface mount packaging connector comprising:
an elastic conductor having a top surface;
an interconnect pad electrically coupled to the elastic conductor, the top surface of the elastic conductor being arranged away from the interconnect pad; and
a conductive layer on the top surface of the elastic conductor, the conductive layer providing an increased electrically conductive surface area.

2. The surface mount packaging connector recited in claim 1 as employed in a land grid array (LGA).

3. The surface mount packaging connector recited in claim 1 wherein the conductive layer is a metal dust.

4. The surface mount packaging connector recited in claim 3 wherein the conductive layer is applied as dirty plasma.

5. The surface mount packaging connector recited in claim 3 wherein the conductive layer has an electrical conductivity within at least 10% of copper electrical conductivity.

6. The surface mount packaging connector recited in claim 5 wherein the conductive layer is composed of a metal from the group consisting of: copper, copper-alloys, gold, gold-alloys, silver, silver-alloys, nickel, and nickel-alloys.

7. The surface mount packaging connector recited in claim 1 wherein the elastic conductor has thermal conductivity between 2 and 15 watts per meter kelvin and volume resistivity between 40 and 120 micro-ohms per centimeter.

8. The surface mount packaging connector recited in claim 1 as employed on a surface for package assembly.

9. The surface mount packaging connector recited in claim 8 wherein the surface for package assembly is a printed circuit board (PCB).

10. The surface mount packaging connector recited in claim 1 wherein the elastic conductor is a glue that has been cured and the conductive layer is formed integrally during the curing of the glue.

11. The surface mount packaging connector recited in claim 1 wherein the elastic conductor is composed such that the elastic conductor can elongate relative to the interconnect pad by at least 10% while remaining in electrical contact therewith.

12. A surface mount packaging connector comprising:
an electrically conductive contact ball having a surface;
an elastic conductor affixed to a portion of said surface and electrically coupled thereto; and
an interconnect pad electrically coupled to the elastic conductor;
wherein the electrically conductive contact ball is elastically movable relative to the interconnect pad while remaining in electrical contact therewith.

13. The surface mount packaging connector recited in claim 12 as employed in a ball grid array (BGA) or an embedded wafer level ball grid array (eWLB).

14. The surface mount packaging connector recited in claim 12 further comprising:
a solderable layer on the elastic conductor at the affixing point between the electrically conductive contact ball and the elastic conductor; and
wherein the electrically conductive contact ball is a solder ball and is thereby affixed through solder processing onto the solderable layer.

15. The surface mount packaging connector recited in claim 14 wherein the solderable layer is a metal dust.

16. The surface mount packaging connector recited in claim 15 wherein the solderable layer is applied as dirty plasma solderable metal dust.

17. The surface mount packaging connector recited in claim 14 wherein the solderable layer has an electrical conductivity within at least 10% of copper electrical conductivity.

18. The surface mount packaging connector recited in claim 17 wherein the solderable layer is composed of a metal from the group consisting of: copper, copper-alloys, gold, gold-alloys, silver, silver-alloys, nickel, and nickel-alloys.

19. The surface mount packaging connector recited in claim 14 wherein the elastic conductor is a glue that has been cured and the solderable layer is formed integrally during the curing of the glue.

20. The surface mount packaging connector recited in claim 14 wherein the electrically conductive contact ball has an electrical conductivity within at least 10% of copper electrical conductivity.

21. The surface mount packaging connector recited in claim 20 wherein the electrically conductive contact ball is composed of a metal from the group consisting of: copper, copper-alloys, gold, gold-alloys, silver, silver-alloys, nickel, nickel-alloys, tin, and tin-alloys.

22. The surface mount packaging connector recited in claim 14 wherein the electrically conductive contact ball has an organic surface protection (OSP) layer affixed to a second portion of the surface of the electrically conductive contact ball.

23. The surface mount packaging connector recited in claim 14 wherein the electrically conductive contact ball has a protective metal layer affixed to a second portion of the surface of the electrically conductive contact ball, the protective metal layer capable of preventing oxidation of the electrically conductive contact ball.

24. The surface mount packaging connector recited in claim 14 wherein the elastic conductor has thermal conductivity between 2 and 15 watts per meter kelvin and volume resistivity between 40 and 120 micro-ohms per centimeter.

25. The surface mount packaging connector recited in claim 14 as employed on the base of a printed circuit board (PCB).

26. The surface mount packaging connector recited in claim 14 wherein the elastic conductor is composed such that movement of the electrically conductive contact ball relative to the interconnect pad can elongate the elastic conductor by at least 10% while remaining in electrical contact therewith.

27. A method for producing a surface mount packaging connector comprising:
providing an interconnect pad;
applying an elastic conductor to the interconnect pad such that the interconnect pad is electrically coupled to the elastic conductor, the elastic conductor having a top surface arranged away from the interconnect pad; and
affixing a electrically conductive contact ball to the top surface of the elastic conductor;
wherein the electrically conductive contact ball is elastically movable relative to the interconnect pad while remaining in electrical contact therewith.

28. The method for producing a surface mount packaging connector recited in claim 27
wherein the elastic conductor is composed such that movement of the electrically conductive contact ball relative to the interconnect pad can elongate the elastic conductor by at least 10% while remaining in electrical contact therewith;
wherein the electrically conductive contact ball has an electrical conductivity within at least 10% of copper electrical conductivity; and
wherein the elastic conductor has thermal conductivity between 2 and 15 watts per meter kelvin and volume resistivity between 40 and 120 micro-ohms per centimeter.

29. The method for producing a surface mount packaging connector recited in claim 27 wherein the elastic conductor is a glue that has been cured and the affixing is performed using the glue.

30. The method for producing a surface mount packaging connector recited in claim 27 wherein the electrically conductive contact ball is composed of a metal from the group consisting of: copper, copper-alloys, gold, gold-alloys, silver, silver-alloys, nickel, nickel-alloys, tin, and tin-alloys.

31. The surface mount packaging connector recited in claim 30 wherein the electrically conductive contact ball has an organic surface protection (OSP) layer affixed to a second portion of the surface of the electrically conductive contact ball.

32. The surface mount packaging connector recited in claim 30 wherein the electrically conductive contact ball has a protective metal layer affixed to a second portion of the surface of the electrically conductive contact ball, the protective metal layer capable of preventing oxidation of the electrically conductive contact ball.

33. A method for producing a surface mount packaging connector comprising:
providing an interconnect pad;
applying an elastic conductor to the interconnect pad such that the interconnect pad is electrically coupled to the elastic conductor, the elastic conductor having a top surface arranged away from the interconnect pad; and
applying a conductive layer as dirty plasma on the top surface of the elastic conductor.

34. The surface mount packaging connector recited in claim 33 wherein the elastic conductor is a glue that has been cured.

35. The surface mount packaging connector recited in claim 34 further comprises:
a solder ball affixed to the conductive layer;
wherein the conductive layer is a solderable layer, and the solder ball is thereby affixed through solder processing onto the solderable layer.

36. The surface mount packaging connector recited in claim 35
wherein the elastic conductor is composed such that movement of the solder ball relative to the interconnect pad can elongate the elastic conductor by at least 10% while remaining in electrical contact therewith;
wherein the conductive layer provides an increased electrically conductive surface with electrical conductivity within at least 10% of copper electrical conductivity; and
wherein the elastic conductor has thermal conductivity between 2 and 15 watts per meter kelvin and volume resistivity between 40 and 120 micro-ohms per centimeter.

37. The surface mount packaging connector recited in claim 33 wherein the conductive layer is composed of a metal from the group consisting of: copper, copper-alloys, gold, gold-alloys, silver, silver-alloys, nickel, and nickel-alloys.
